(19) United States
(12) Patent Application Publication
(10) Pub. No.: US 2009/0051459 A1
(43) Pub. Date: Feb. 26, 2009

(54) FILTER

(75) Inventors: Yuichi Miyata, Nagano-pref (JP); Hiroyuki Morikaku, Nagano-pref (JP)

Correspondence Address: BURR & BROWN, PO BOX 7068, SYRACUSE, NY, 13261-7068, US

(73) Assignee: Soshin Electric Co., Ltd., Saku- City (JP)

(21) Appl. No.: 11/817,423

(22) PCT Filed: Mar. 17, 2006
(86) PCT No.: PCT/JP2006/305398

§ 371 Date: Aug. 30, 2007

(30) Foreign Application Priority Data
Mar. 18, 2005 (JP) 2005-078801

(51) Int. Cl. H03H 7/42

(52) U.S. Cl. 333/25

(57) ABSTRACT

A filter is provided with one unbalanced input terminal, a first balanced output terminal and a second balanced output terminal. A primary coil is connected between a connecting point, which is of a second capacitor and a third capacitor, and GND. Furthermore, a secondary coil is connected between the first balanced output terminal and the second balanced output terminal, and the primary coil and the secondary coil are magnetically coupled.

### TECHNICAL FIELD

The present invention relates to a filter for realizing an unbalanced input/balanced output system or a balanced input/unbalanced output system without employing a balun, and more particularly to a filter suitable for use as a filter having a passband ranging from 76 to 108 MHz.

### BACKGROUND ART

As shown in FIG. 5, a bandpass filter 200, for example, usually has an unbalanced input terminal 202 and an unbalanced output terminal 204, providing an unbalanced input/unbalanced output system.

If the bandpass filter 200 is to be connected to a balanced-input high-frequency amplifying circuit 206, for example, then a balun (unbalanced to balanced converter) 208 is connected between the unbalanced output terminal 204 of the bandpass filter 200 and the high-frequency amplifying circuit 206.

As shown in FIG. 6, the balun 208 has an unbalanced line 212 connected to an unbalanced input terminal 210, a first balanced line 216a connected between a first balanced output terminal 214a and ground, and a second balanced line 216b connected between a second balanced output terminal 214b and ground (see, for example, Patent Document 1). The balun 208 is constructed as a distributed-constant circuit having a plurality of striplines, each having an about λ/4 length, provided in a dielectric substrate, for example. The balun 208 is thus small in size, contributing to a size reduction of an electric device that includes the bandpass filter 200 and the balun 208.

Heretofore, there has been proposed a laminated electronic component having a base which comprises a dielectric layer and a magnetic layer that are joined to each other (see, for example, Patent Document 2). The laminated electronic component is solely aimed at preventing the product from suffering warpage, delamination, and cracking by adding a dummy layer thereto. It has been unclear, however, if the laminated electronic component can achieve an object to incorporate an FM radio receiver and/or an FM transmitter in a portable device.

Patent Document 1: Japanese Laid-Open Patent Publication No. 2003-7538

Patent Document 2: Japanese Laid-Open Patent Publication No. 2003-37022

### DISCLOSURE OF THE INVENTION

The conventional balun 208 is applied to a high passband in the vicinity of 2.4 GHz, for example. If the balun 208 is applied to a bandpass filter having a passband in a range from 76 to 108 MHz or in part of the range, then the lengths of the striplines need to be increased about 24 times, and the balun 208 cannot be reduced in size.

Recently, it has been considered to incorporate an FM radio receiver and/or an FM transmitter in a portable device (including an electronic device) such as a cellular phone or the like. However, since the balun 208 connected to the bandpass filter cannot be reduced in size, it is difficult to fabricate such an application.

The present invention has been made in view of the above difficulties. It is an object of the present invention to provide a filter according to an unbalanced input/balanced output system or a balanced input/unbalanced output system without employing a balun, the filter being reduced in size and allowing an FM radio receiver and/or an FM transmitter to be incorporated in a portable device, for example.

According to the present invention, there is provided a filter of the unbalanced output type having a coil connected between an input stage and ground, wherein the coil is divided into a primary coil and a secondary coil which are magnetically coupled to each other, the primary coil having opposite ends connected respectively to corresponding balanced input terminals.

According to the present invention, there is also provided a filter of the unbalanced input type having a coil connected between an output stage and ground, wherein the coil is divided into a primary coil and a secondary coil which are magnetically coupled to each other, the secondary coil having opposite ends connected respectively to corresponding balanced output terminals.

In each of the above filters according to the present invention, the electric power of the primary coil is transmitted to the secondary coil based on the magnetic energy due to a mutually inductive action.

Each of the filters according to the present invention can realize an unbalanced input/balanced output system or a balanced input/unbalanced output system without employing a balun, and are reduced in size. In other words, filters having a passband in a range from 76 to 108 MHz or in part of the range, and are reduced in size. With each of the filters according to the present embodiment being incorporated in a portable device, for example, it is possible to incorporate an FM radio receiver and/or an FM transmitter in the portable device.

Each of the filters may be formed in a base body comprising a dielectric member and a magnetic member that are joined to each other. The primary coil and the secondary coil should preferably be formed in at least the magnetic member.

Further preferably, a plurality of electrodes for forming the primary coil may be formed on a first forming region of the magnetic member, and a plurality of electrodes for forming the secondary coil may be formed on a second forming region which is positioned above or below the first forming region of the magnetic member.

As described above, each of the filters according to the present embodiment is reduced in size, making it possible to incorporate an FM radio receiver and/or an FM transmitter in a portable device, for example.

### BRIEF DESCRIPTION OF THE DRAWINGS

FIG. 1 is a circuit diagram of a filter according to a comparative example;

FIG. 2 is a circuit diagram of a filter according to an embodiment of the present invention;

FIG. 3 is a perspective view showing an appearance of the filter according to the embodiment of the present invention;

FIG. 4 is an exploded perspective view of the filter according to the embodiment of the present invention;

FIG. 5 is a block diagram showing an application in which a conventional bandpass filter is used; and

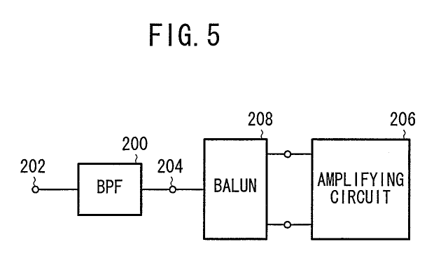

FIG. 6 is a diagram showing a balun connected to the conventional bandpass filter.

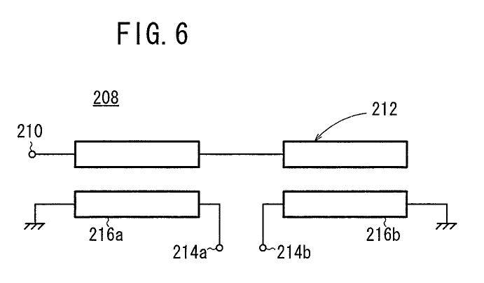

### BEST MODE FOR CARRYING OUT THE INVENTION

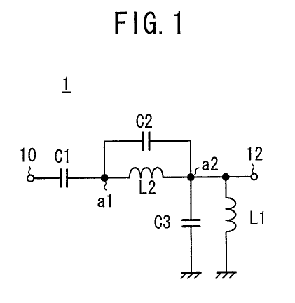

A filter according to an embodiment of the present invention as applied to a filter for use in an FM radio receiver and/or an FM transmitter, for example, will be described below with reference to FIGS. 1 through 4.

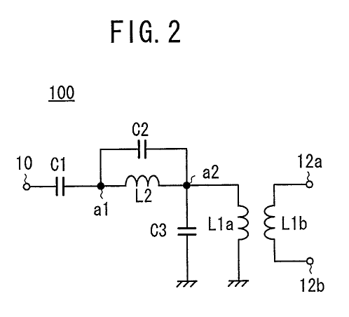

Prior to describing a filter 100 (see FIG. 2) according to the embodiment of the present invention, a filter according to an unbalanced input/unbalanced output system (a filter 1 according to a comparative example) will be described for comparison below with reference to FIG. 1.

As shown in FIG. 1, the filter 1 according to the comparative example has a circuit arrangement including a first capacitor C1 and a second capacitor C2 that are connected in series with each other between an unbalanced input terminal 10 and an unbalanced output terminal 12, a third capacitor C3 and a first coil L1 that are connected parallel to each other between the unbalanced output terminal 12 and GND (ground), and a second coil L2 connected between a first junctional between the first capacitor C1 and the second capacitor C2 and a second junction a2 between the second capacitor C2 and the third capacitor C3. Therefore, a single coil (the first coil L1) is connected between the output stage of the filter 1 and GND.

As shown in FIG. 2, the filter 100 according to the present embodiment includes an unbalanced input terminal 10, two balanced output terminals (a first balanced output terminal 12a and a second balanced output terminal 12b), a primary coil L1a connected between a junction a2 between a second capacitor C2 and a third capacitor C3, and GND, and a secondary coil L1b connected between the first balanced output terminal 12a and the second balanced output terminal 12b.

In other words, the filter 100 according to the present embodiment has an arrangement wherein the first coil L1 of the filter 1 according to the comparative example is divided into the primary coil L1a and the secondary coil L1b that are magnetically coupled to each other, and the secondary coil L1b has its opposite ends connected respectively to the corresponding first balanced output terminal 12a and the corresponding second balanced output terminal 12b.

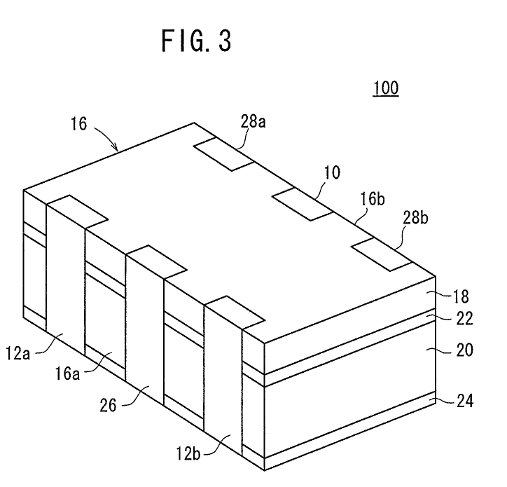

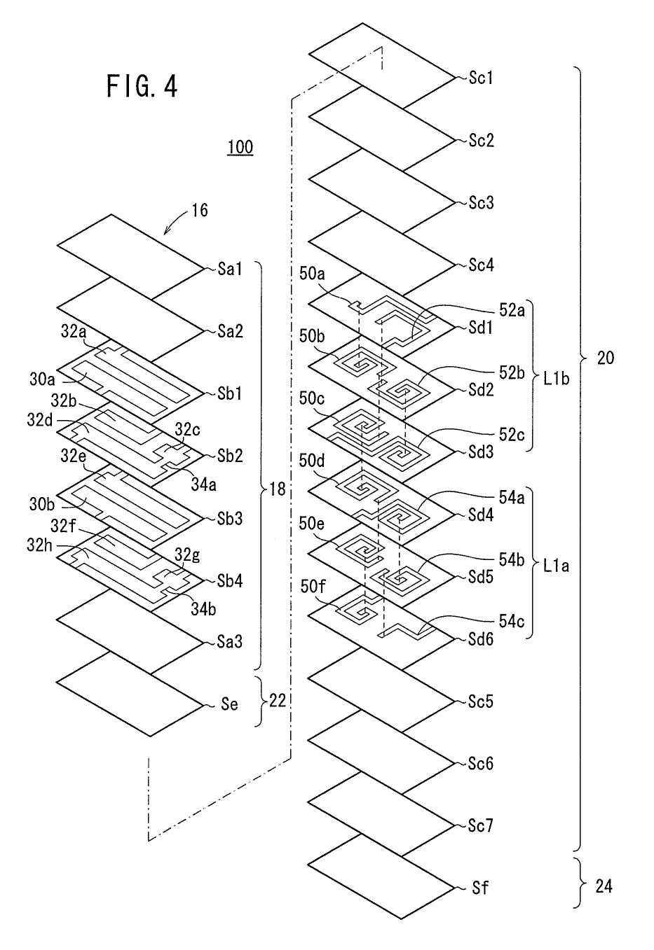

Specific structural details of the filter 100 according to the present embodiment will be described below with reference to FIGS. 3 and 4.

As shown in FIG. 3, the filter 100 according to the present embodiment has a base body 16 including a dielectric member 18, a magnetic member 20, a joint member 22 joining the dielectric member 18 and the magnetic member 20 to each other, and a dummy member 24 joined to the lower end of the magnetic member 20, the members being sintered into an integral assembly.

As indicated by Patent Document 2, the dummy member 24 is aimed at preventing the base body 16 from suffering warpage, delamination, and cracking.

In the filter 100 according to the present embodiment, as shown in FIG. 4, the dielectric member 18 comprises a plurality of laminated dielectric layers including, successively from above, a first dummy layer Sa1, a second dummy layer Sa2, first through fourth capacitor electrode layers Sb1 through Sb4, and a third dummy layer Sa3. Each of the first dummy layer Sa1, the second dummy layer Sa2, the first through fourth capacitor electrode layers Sb1 through Sb4, and the third dummy layer Sa3 is constructed as a single layer or a plurality of layers.

The magnetic member 20 comprises a plurality of laminated magnetic layers including, successively from above, first through fourth dummy layers Sc1 through Sc4, first through sixth coil electrode layers Sd1 through Sd6, and fifth through seventh dummy layers Sc5 through Sc7. Each of the first through fourth dummy layers Sc1 through Sc4, the first through sixth coil electrode layers Sd1 through Sd6, and the fifth through seventh dummy layers Sc5 through Sc7 is constructed as a single layer or a plurality of layers.

The joint member 22 comprises a single intermediate layer Se which is constructed as a single layer or a plurality of layers.

The dummy member 24 comprises a single dummy layer Sf which is constructed as a single layer or a plurality of layers.

Each of the first through third dummy layers Sa1 through Sa3 of the dielectric member 18 and the first through seventh dummy layers Sc1 through Sc7 of the magnetic member 20 is aimed at preventing the base body 16 from suffering warpage, delamination, and cracking, as with the dummy member 24.

As shown in FIG. 3, the first balanced output terminal 12a, the second balanced output terminal 12b, and a ground terminal 26 are disposed on a first side surface 16a of the base body 16, and a first connection terminal 28a corresponding to the first junctional (see FIG. 2), a second connection terminal 28b corresponding to the second junction a2 (see FIG. 2), and the unbalanced input terminal 10 are disposed on a second side surface 16b (opposite to the first side surface 16a) of the base body 16.

As shown in FIG. 4, the first through fourth capacitor electrode layers Sb1 through Sb4 and the first through sixth coil electrode layers Sd1 through Sd6 have various electrodes. Specifically, the first capacitor electrode layer Sb1 has on a principal surface thereof a first ground electrode 30a having an end connected to the ground terminal 26 and a first capacitor electrode 32a having an end connected to the first connection terminal 28a.

The second capacitor electrode layer Sb2 has on a principal surface thereof a second capacitor electrode 32b having an end connected to the unbalanced input terminal 10, a third capacitor electrode 32c having an end connected to the second connection terminal 28b, and a fourth capacitor electrode 32d connected to the third capacitor electrode 32c through a lead electrode 34a.

The third capacitor electrode layer Sb3 has on a principal surface thereof a second ground electrode 30b and a fifth capacitor electrode 32e which are similar respectively to the first ground electrode 30a and the first capacitor electrode 32a on the first capacitor electrode layer Sb1.

The fourth capacitor electrode layer Sb4 has on a principal surface thereof sixth through eighth capacitor electrodes 32f through 32h and a lead electrode 34b which are similar respectively to the second through fourth capacitor electrodes 32b through 32d and the lead electrode 34a on the second capacitor electrode layer Sb2.

The second capacitor electrode 32b and the third capacitor electrode 32c face the first capacitor electrode 32a and the fifth capacitor electrode 32e, and the fourth capacitor electrode 32d faces the first ground electrode 30a and the second ground electrode 30b.

The sixth capacitor electrode 32f and the seventh capacitor electrode 32g face the fifth capacitor electrode 32e, and the eighth capacitor electrode 32h faces the second ground electrode 30b.

The first through sixth coil electrode layers Sd1 through Sd6 have on respective principal surfaces thereof respective first through sixth coil electrodes 50a through 50f which make up the second coil L2.

The first through third coil electrode layers Sd1 through Sd3 have on respective principal surfaces thereof respective seventh through ninth coil electrodes 52a through 52c which make up the secondary coil Llb. The fourth through sixth coil electrode layers Sd4 through Sd6 have on respective principal surfaces thereof respective tenth through twelfth coil electrodes 54a through 54c which make up the primary coil L1a.

The first coil electrode 50a on the principal surface of the first coil electrode layer Sd1 has an end connected to the second connection terminal 28b, and the seventh coil electrode 52a has an end connected to the second balanced output terminal 12b.

The ninth coil electrode 52c on the principal surface of the third coil electrode layer Sd3 has an end connected to the first balanced output terminal 12a, and the tenth coil electrode 54a on the principal surface of the fourth coil electrode layer Sd4 has an end connected to the ground terminal 26.

The sixth coil electrode 50f on the principal surface of the sixth coil electrode layer Sd6 has an end connected to the first connection terminal 28a, and the twelfth coil electrode 54c has an end connected to the second connection terminal 28b.

The first through sixth coil electrodes 50a through 50f are electrically connected to each other by via holes, and the seventh through ninth coil electrodes 52a through 52c are electrically connected to each other by via holes. The tenth through twelfth coil electrodes 54a through 54c are electrically connected to each other by via holes.

With the above arrangement, the first ground electrode 30a, the fourth capacitor electrode 32d, the second ground electrode 30b, and the eighth capacitor electrode 32h make up a laminated structure providing the third capacitor C3 shown in FIG. 2. The first capacitor electrode 32a, the second capacitor electrode 32b, the fifth capacitor electrode 32e, and the sixth capacitor electrode 32f make up a laminated structure providing the first capacitor C1. The first capacitor electrode 32a, the third capacitor electrode 32c, the fifth capacitor electrode 32e, and the seventh capacitor electrode 32g make up a laminated structure providing the second capacitor C2.

The first through sixth coil electrodes 50a through 50f make up the second coil L2 shown in FIG. 2, the seventh through ninth coil electrodes 52a through 52c make up the secondary coil L1b, and the tenth through twelfth coil electrodes 54a through 54c make up the primary coil L1a.

Since the tenth through twelfth coil electrodes 54a through 54c of the primary coil L1a are formed on a first forming region (the fourth through sixth coil electrode layers Sd4 through Sd6) of the magnetic member 20, and the seventh through ninth coil electrodes 52a through 52c of the secondary coil L1b are formed on a second forming region (the first through third coil electrode layers Sd1 through Sd3) of the magnetic member 20, the primary coil L1a and the secondary coil L1b are magnetically coupled to each other. Accordingly, the electric power of the primary coil L1a is transmitted to the secondary coil L1b based on the magnetic energy due to a mutually inductive action.

Since the filter 100 according to the present embodiment has an arrangement wherein the coil L1 (see FIG. 1) in the output stage of the filter 1 according to the comparative example is divided into the primary coil L1a and the secondary coil L1b, the opposite ends of the secondary coil L1b are connected respectively to the corresponding first and second balanced output terminals 12a, 12b, and the electric power of the primary coil L1a is transmitted to the secondary coil L1b by a mutually inductive action, the filter 100 can realize an unbalanced input/balanced output system or a balanced input/unbalanced output system without employing a balun, and is reduced in size.

In other words, the filter 100 having a passband in a range from 76 to 108 MHz or in part of the range is reduced in size. With the filter 100 according to the present embodiment being incorporated in a portable device, for example, it is possible to incorporate an FM radio receiver and/or an FM transmitter in the portable device.

Particularly, according to the present embodiment, inasmuch as the filter 100 is formed in the base body 16 comprising the dielectric member 18 and the magnetic member 20 that are joined to each other, the primary coil, L1a, the secondary coil L1b, and the second coil L2 can be formed in the magnetic member 20 whose magnetic permeability constant is high, and the first through third capacitors C1 through C3 can be formed in the dielectric member 18 whose dielectric constant is high. This arrangement further contributes to a size reduction of the filter 100.

According to the present embodiment, furthermore, since the tenth through twelfth coil electrodes 54a through 54c for forming the primary coil L1a are formed on the first forming region (the fourth through sixth coil electrode layers Sd4 through Sd6) of the magnetic member 20, and the seventh through ninth coil electrodes 52a through 52c for forming the secondary coil L1b are formed on the second forming region (the first through third coil electrode layers Sd1 through Sd3) of the magnetic member 20, the first coil L1 in the output stage of the filter 1 according to the comparative example can simply be divided into the primary coil L1a and the secondary coil L1b. Consequently, the filter 100 can realize an unbalanced input/balanced output system or a balanced input/unbalanced output system without employing a balun. The filter 100, which is reduced in size, can be fabricated easily and inexpensively.

If it is assumed that the first ground electrode 30a and the first capacitor electrode 32a on the first capacitor electrode layer Sb1 and the second through fourth capacitor electrodes 32b through 32d on the second capacitor layer Sb2 are used as a single array pattern, then according to the present embodiment, as shown in FIG. 4, two such array patterns are juxtaposed in the laminated directions of the dielectric layers of the dielectric member 18. Therefore, the capacitance of each of the first through third capacitors C1 through C3 is increased for a further reduction in the size of the filter 100. One array pattern, two array patterns, or three or more array patterns can be laminated.

The inductance of each of the seventh through ninth coil electrodes 52a through 52c can be changed to adjust the impedance of the balanced output. The inductance of each of the seventh through ninth coil electrodes 52a through 52c may be changed by changing the widths of some or all of the seventh through ninth coil electrodes 52a through 52c, changing the cross-sectional area of inside-diameter portions (portions surrounded by the electrodes), or changing the number of turns thereof.

In the above embodiment, the present invention is applied to an unbalanced-input/balanced-output filter. The present invention is also applicable to a balanced-input/unbalanced-output filter. In such a case, the secondary coil Lb1 is used as a primary coil, and the primary coil. L1a as a secondary coil. The unbalanced input terminal 10 may be used as an unbalanced input terminal, the first balanced output terminal 12a as a first balanced input terminal, and the second balanced output terminal 12b as a second balanced input terminal.

The filter according to the present invention is not limited to the above embodiment, but may take various arrangements without departing from the scope of the invention.

1-6. (canceled)

7. A filter of the unbalanced output type having a coil connected between an input stage and ground, wherein
said coil is divided into a primary coil and a secondary coil which are magnetically coupled to each other;
said primary coil having opposite ends connected respectively to corresponding balanced input terminals.

8. A filter according to claim 7, which formed in a base body comprising a dielectric member and a magnetic member that are joined to each other.

9. A filter according to claim 8, wherein said primary coil and said secondary coil are formed in at least said magnetic member.

10. A filter according to claim 9, wherein a plurality of electrodes for forming said primary coil are formed on a first forming region of said magnetic member; and
a plurality of electrodes for forming said secondary coil are formed on a second forming region which is positioned above or below said first forming region of said magnetic member.

11. A filter according to claim 7, which has a passband in a range from 76 to 108 MHz or in part of the range.

12. A filter of the unbalanced input type having a coil connected between an output stage and ground, wherein
said coil is divided into a primary coil and a secondary coil which are magnetically coupled to each other;
said secondary coil having opposite ends connected respectively to corresponding balanced output terminals.

13. A filter according to claim 12, which is formed in a base body comprising a dielectric member and a magnetic member that are joined to each other.

14. A filter according to claim 13, wherein said primary coil and said secondary coil are formed in at least said magnetic member.

15. A filter according to claim 14, wherein a plurality of electrodes for forming said secondary coil are formed on a second forming region which is positioned above or below said first forming region of said magnetic member.

16. A filter according to claim 12, which has a passband in a range from 76 to 108 MHz or in part of the range.
